(19) United States
(12) Patent Application Publication
(10) Pub. No.: US 2015/0349234 A1
(43) Pub. Date: Dec. 3, 2015

(54) Methods Of Making A Specialty Junction Thermocouple For Use In High Temperature And Corrosive Environments

(71) Applicant: Watlow Electric Manufacturing Company, St. Louis, MO (US)

(72) Inventors: Eric Allain, Naperville, IL (US); Hongy Lin, Chesterfield, MO (US)

(21) Appl. No.: 14/823,330

(22) Filed: Aug. 11, 2015

Related U.S. Application Data
(62) Division of application No. 13/486,717, filed on Jun. 1, 2012.

(51) Int. Cl. H01L 35/34; H01L 35/32; H01R 43/02; G01K 7/02

(52) U.S. Cl. CPC H01L 35/34; G01K 7/02; H01L 35/32; H01R 43/0221

(57) ABSTRACT

A method of manufacturing a thermocouple includes forming a hot junction between the distal end portions of first and second thermocouple wires. The hot junction defines a splice such that the first thermocouple wire and the second thermocouple wire are in direct contact at their distal end portions. A refractory coating is applied over the hot junction.

### CROSS-REFERENCE TO RELATED APPLICATIONS

This application is a divisional of U.S. patent application Ser. No. 13/486,717, filed on Jun. 1, 2012, the entire content of which is incorporated herein by reference.

### FIELD

The present disclosure relates to thermocouples, and more specifically to thermocouples with high temperature endurance and improved corrosion resistance.

### BACKGROUND

The statements in this section merely provide background information related to the present disclosure and may not constitute prior art.

A thermocouple is known to include a hot junction formed by bonding a pair of conductive wires of dissimilar metals. The hot junction is placed proximate an object to be measured. The other end of the conductive wires, known as cold junction or reference junction, is connected to a measuring system. The thermocouple generates an open-circuit voltage, which is proportional to the temperature difference between the hot and reference junctions. The temperature at the hot junction can be determined based on the generated voltage and the temperature of the reference junction.

Thermocouples are widely used because they are inexpensive, interchangeable and can measure a wide range of temperatures. One of the limitations with thermocouples is that the hot junction is susceptible to thermal and physical damage. It is known to use a metal sheath to surround and protect the hot junction. The metal sheath, however, affects heat transfer from the object to be measured to the hot junction and thus contributes to errors in the temperature measurements. In the absence of the metal sheath, however, the thermocouple can be easily damaged when used in elevated temperatures or corrosive environment.

### SUMMARY

In one form, a method of manufacturing a thermocouple comprises: placing a distal end portion of a first thermocouple wire into physical contact with a distal end portion of a second thermocouple wire to form a splice; laser welding the splice to form a hot junction; and coating the hot junction with a refractory material.

In another form, a method of manufacturing a thermocouple comprises: placing a distal end portion of a first thermocouple wire into physical contact with a distal end portion of a second thermocouple wire to form a splice; forming a hot junction by laser-welding the splice to form a weld; applying a refractory coating on the entire hot junction and at least a section of the distal end portions of the first thermocouple wire and the second thermocouple wire; and placing the first and second thermocouple wires and the hot junction into a ceramic insulator body.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way.

In order that the invention may be well understood, there will now be described an embodiment thereof, given by way of example, reference being made to the accompanying drawing, in which:

FIG. 1 is a perspective view of a typical thermocouple;

FIG. 2 is a schematic view of a thermocouple having a hot junction in the form of a lap weld and constructed in accordance with the teachings of the present disclosure;

FIG. 3 is a schematic view of a thermocouple having a hot junction in the form of a butt weld and constructed in accordance with the teachings of the present disclosure;

FIG. 4 is a perspective view of a thermocouple assembly constructed in accordance with the teachings of the present disclosure;

FIG. 5 is an enlarged perspective view of portion A of FIG. 4;

FIG. 6 is a bar chart showing life of thermocouples without a coating, with an alumina coating, and with a silica coating in accelerated life testing conditions;

FIG. 7 shows microscopic images of a thermocouple having a silica coating and constructed in accordance with the teachings of the present disclosure; and

FIG. 8 is a flow chart of a method of manufacturing a thermocouple of the present disclosure.

Corresponding reference numerals indicate corresponding parts throughout the several views of the drawings.

### DETAILED DESCRIPTION

The following description is merely exemplary in nature and is not intended to limit the present disclosure, application, or uses.

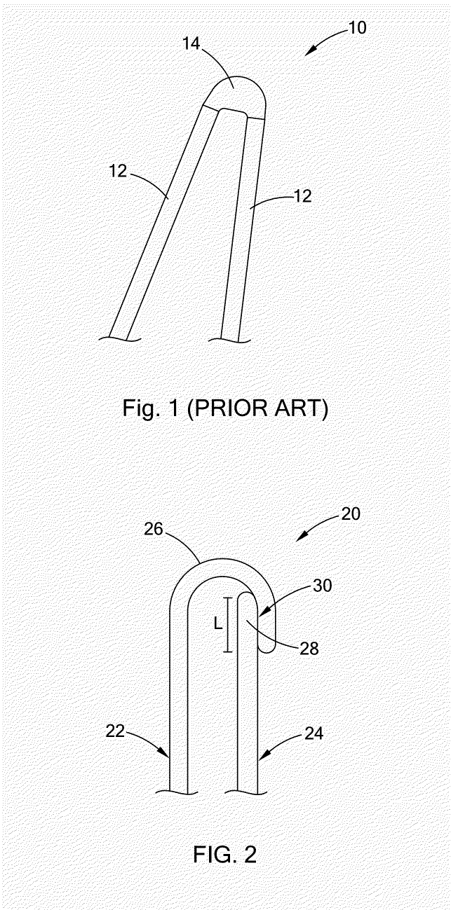

Referring to FIG. 1, a typical thermocouple 10 is shown to include a pair of conductive wires 12 of dissimilar metals, which are joined to form a hot junction 14. As shown, the pair of conductive wires 12 are arranged to define a V shape with their distal ends placed adjacent to each other. The distal ends of the conductive wires 12 are welded together to form a ball weld, which defines the hot junction 14.

Referring to FIG. 2, a thermocouple 20 constructed in accordance with the teachings of the present disclosure includes a first thermocouple wire 22 and a second thermocouple wire 24. The first thermocouple wire 22 defines a distal end portion 26. The second thermocouple wire 24 defines a distal end portion 28. The distal end portion 26 of the first thermocouple wire 22 is configured to have a curved portion such that the distal end portion 26 overlaps and is in direct contact with the distal end portion 28 of the second thermocouple wires 24 along a length L. A hot junction 30 is formed by laser welding the distal end portions 26 and 28 of the first and second thermocouple wires 22 and 24 to form a weld.

As shown in FIG. 2, the hot junction 30 is formed by a lap weld (lap splice joint). The lap weld is formed by overlapping a portion of the distal ends portions 26 and 28 of the first and second thermocouple wires 22 and 24. As shown, the distal end portion 26 of the first thermocouple wire 22 overlaps the distal end portion 28 of the second thermocouple wire 24 a length L along the longitudinal direction of the second thermocouple wire 24. Therefore, the hot junction 30, which is formed by the lap weld, extends a length L.

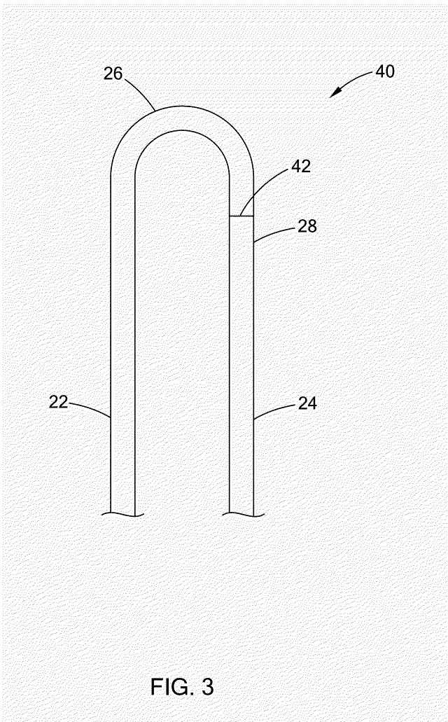

Referring to FIG. 3, a thermocouple 40 constructed in accordance with the teachings of the present disclosure may have a hot junction 42, which is formed by a butt weld (a butt splice joint). The butt weld may be formed by aligning the distal end portions 26 and 28 of the first and second thermocouple wires 22 and 24 such that the first and second thermocouple wires 22 and 24 do not overlap along the longitudinal direction of the second thermocouple wire 24.

The first thermocouple wire 22 and the second thermocouple wire 24 comprise a material selected from the group consisting of platinum and platinum-rhodium alloys. It is understood that the first and second thermocouple wires 22 and 24 include dissimilar metals. Therefore, when one of the first and second thermocouple wires 22 and 24 includes platinum, the other one of the first and second thermocouple wires 22 and 24 includes platinum-rhodium alloys.

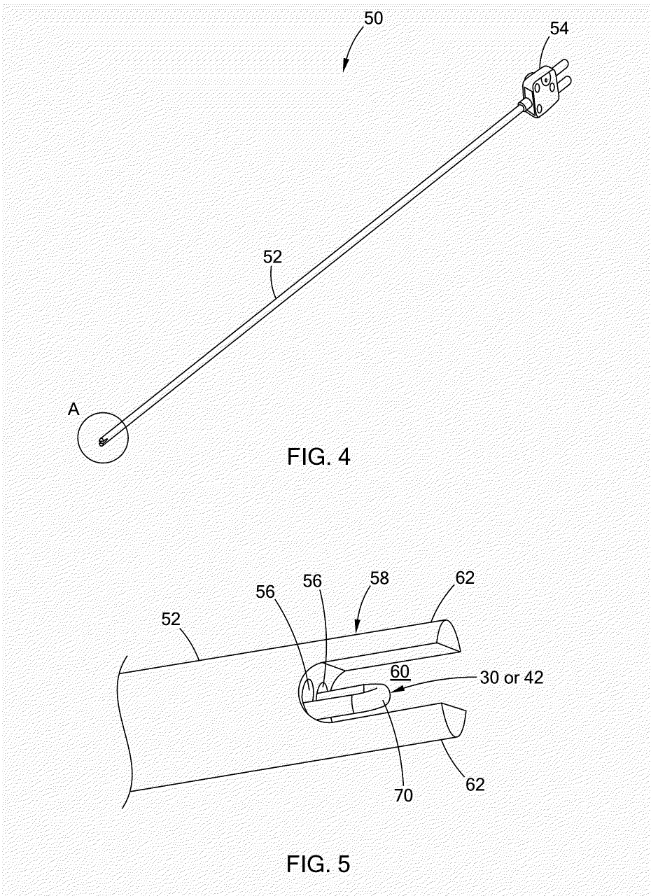

Referring to FIGS. 4 and 5, a thermocouple assembly 50 includes the thermocouple 20 or 40, a ceramic insulator body 52, and a connector 54. The first and second thermocouple wires 22 and 24 have proximal ends (not shown) connected to the connector 54, which is adapted for connection to a controller or other temperature processing device/circuit. The ceramic insulator body 52 receives and protects the first and second thermocouple wires 22 and 24 and the hot junction 30 or 42 against any physical contact.

As clearly shown in FIG. 5, the ceramic insulator body 52 defines a pair of passages 56 extending along the length of the ceramic insulator body 52 and a distal end portion 58 having a recess 60. The pair of thermocouple wires 22 and 24 are received in the passages 56. The distal end portions 26 and 28 of the first and second thermocouple wires 22 and 24 and the hot junction 30 or 42 are disposed within the recess 60. The distal end portion 58 of the ceramic insulator body 52 includes a pair of protecting arms 62 opposing to each other. When the hot junction 30 or 42 is disposed in the recess 60, the hot junction 30 or 42 is disposed between the pair of protecting arms 62 such that the hot junction 30 or 42 is protected against any physical contact with surrounding environment.

The thermocouple assembly 50 further includes a refractory coating 70 applied over the hot junction 30 or 42. The refractory coating 70 may include ceramic materials or oxides materials. For example, the refractory coating 70 may include a material selected from the group consisting of alumina (Al₂O₃) and silica (SiO₂). The refractory coating 70 is applied over the entire hot junction 30 or 42 and over at least a section of the distal end portions 26 and 28 of the first and second thermocouple wires 22 and 24. The refractory coating 70 may be applied by a process selected from the group consisting of physical vapor deposition, chemical vapor deposition, plasma enhanced chemical vapor deposition, plasma spray, and thick film. The refractory coating 70 has a continuous thickness between approximately 50 microns and approximately 150 microns.

The refractory coating 70 acts as a protection barrier against severe corrosion caused by, for example, silicon vapors at temperatures above 1450° C. With the protection of the refractory coating 70, the hot junction 30 or 42 is corrosion resistant, has prolonged life, and can be used in high temperature furnaces that are used to produce silicon ingots for the photovoltaic or semiconductor industries. Moreover, the life of the thermocouple further depends on the densification of the refractory coating 70. Therefore, to further prolong the life of a thermocouple for use in Si vapor environment, the densification of ceramic powder of the refractory coating 70 is made greater than 95% theoretical density to eliminate open porosity.

In addition, the refractory coating 70 also increases the mechanical strength of the thermocouple wires that includes Pt. Noble metals such as Pt have relatively low elastic modulus and low creep resistance. The refractory coating 70 of ceramic materials or oxides has relatively high creep resistance at high temperatures. When the refractory coating 70 is applied on a section of the thermocouple wires 22 and 24 that include Pt, the refractory coating 70 may protect the thermocouple wires 22 and 24 against gravity exerting on Pt wire, thereby reducing likelihood of tensile failure.

The thermocouples 20 and 40 or the thermocouple assembly 50 of the present disclosure have high temperature endurance, improved corrosion resistance, and prolonged life. The hot junction, which is formed by a lap weld or a butt weld, has low residual stress. The low-residual stress allows the refractory coating 70 to maintain its integrity without cracking and/or flaking off due to stress release. With the protection of the refractory coating 70, platinum and platinum-rhodium alloys, which would otherwise more susceptible to thermal and physical damage, may be used to form the first and second thermocouple wires, 22 and 24. Platinum and platinum-rhodium alloys result in a clean weld, thereby further prolonging the life of the thermocouple.

Further, the refractory coating 40 is applied on the entire surface of the hot junction 30 and a section of the first and second thermocouple wires 22 and 24. The refractory materials with low porosities not only have relatively high thermal conductivity to conduct heat from the object to be measured to the hot junction, but also prevents Si vapor from the surrounding environment from reacting with Pt in the underlying thermocouple wires.

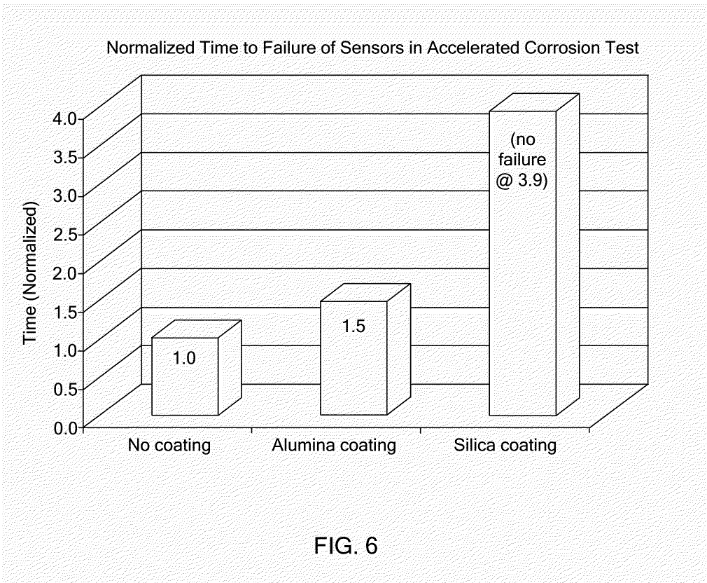

Referring to FIG. 6, test results for thermocouples with/without refractory coatings 70 in terms of life of thermocouples are shown. The thermocouples are subjected to accelerated corrosion tests and the life of the thermocouples is normalized. As shown, when a thermocouple without a refractory coating has a normalized life of 1.0, the thermocouple with an alumina coating and a silica coating have a normalized life of 1.5 and 3.9, respectively. Therefore, the alumina coating increases the life of a thermocouple without a refractory coating by 50%, whereas the silica coating almost quadruples the life of a thermocouple without a refractory coating.

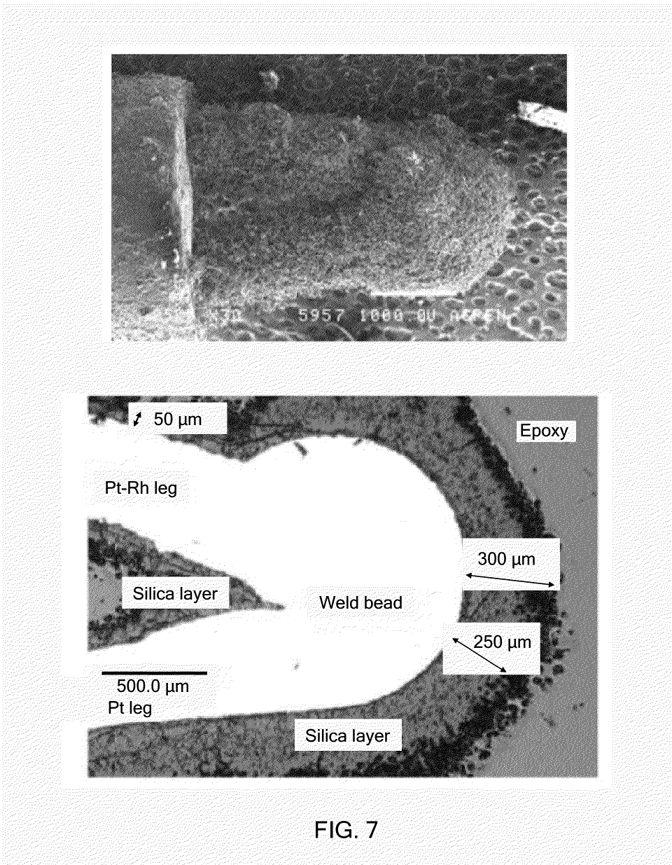

FIG. 7 shows microscopic images of a thermocouple with a silica coating after the thermocouple is subjected to accelerated corrosion tests. As shown, the silica coating maintains its integrity after the accelerated corrosion tests and thus can reliably isolate and protect the hot junction and the thermocouple wires from corrosive vapors in the surrounding environment. Therefore, the thermocouple with the refractory coating, particularly a silica coating, is corrosion-resistant.

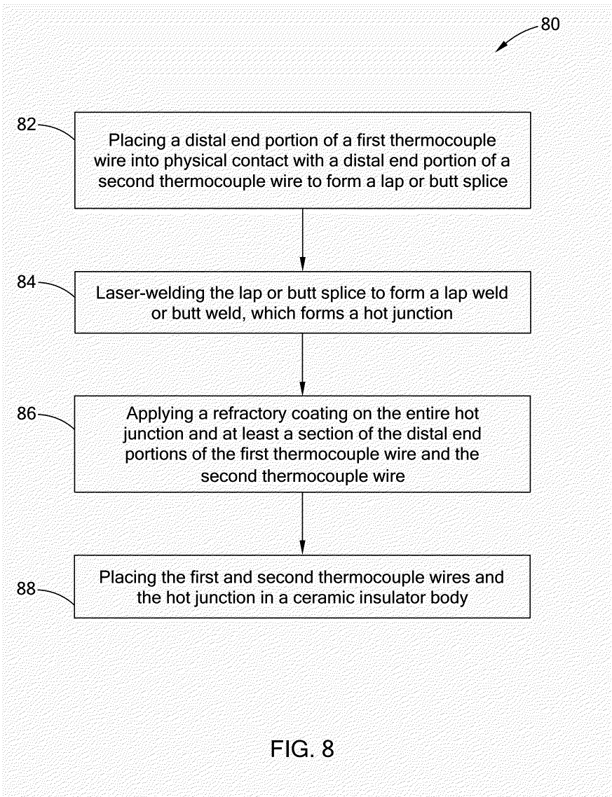

Referring to FIG. 8, a method 80 of manufacturing a thermocouple includes placing a distal end portion 26 of a first thermocouple wire 22 into physical contact with a distal end portion 28 of a second thermocouple wire 24 to form a splice in step 82. The distal end portions 26 and 28 of the first and second thermocouples 22 and 24 may be placed to overlap a length in order to form a lap splice joint or may be aligned without overlapping to form a but splice joint. The splice is laser-welded to form a lap weld or a butt weld, which forms a hot junction 30 or 42 in step 84. The hot junction 30 or 42 is then coated by a refractory material to form a refractory coating 70 in step 86. The refractory coating 70 is applied on the entire hot junction 30 or 42 and at least a section of the distal end portions 26 and 28 of the first and second thermocouple wires 22 and 24. The refractory coating 70 may be applied by a process selected from the group consisting of physical vapor deposition, chemical vapor deposition, plasma enhanced chemical vapor deposition, plasma spray, and thick film. Thereafter, the first and second thermocouple wires 22 and 24 and the hot junction 30 or 42 are then placed within a ceramic insulator body 52 to form a thermocouple assembly 50 in step 88.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method of manufacturing a thermocouple comprising:
placing a distal end portion of a first thermocouple wire into physical contact with a distal end portion of a second thermocouple wire to form a splice;
laser welding the splice to form a hot junction; and
coating the hot junction with a refractory material.

2. The method according to claim 1 further comprising:
coating the entire hot junction and at least a portion of the distal end portions of the first thermocouple wire and the second thermocouple wire; and
placing the joined thermocouple wires and the hot junction within a ceramic insulator body.

3. The method according to claim 1, wherein the distal end portion of the first thermocouple wire and the distal end portion of the second thermocouple wire are placed into physical contact by a butt splice.

4. The method according to claim 1, wherein the distal end portion of the first thermocouple wire and the distal end portion of the second thermocouple wire are placed into physical contact by a lap splice.

5. The method according to claim 1, wherein the coating of refractory material is applied by a process selected from the group consisting of physical vapor deposition, chemical vapor deposition, plasma enhanced chemical vapor deposition, plasma spray, and thick film.

6. The method according to claim 1, wherein the coating of refractory material defines a continuous thickness between 50 microns and 150 microns.

7. The method according to claim 1, wherein the coating of refractory material is selected from the group consisting of Al₂O₃ and SiO₂.

8. The method according to claim 1, wherein the first thermocouple wire and the second thermocouple wire comprise a material selected from the group consisting of platinum and platinum-rhodium alloys.

9. The method according to claim 2, wherein ceramic insulator body defines a pair of passages extending along the length of the ceramic insulator body and a distal end portion having a recess, such that placing the joined thermocouple wires and the hot junction within the ceramic insulator body includes placing the first and second thermocouple wires into the passages and placing the distal end portions of the first and second thermocouple wires and the hot junction within the recess.

10. The method according to claim 8, wherein the first thermocouple wire and the second thermocouple wire comprise dissimilar materials.

11. The method according to claim 9, wherein the ceramic insulator body comprises a distal end including a pair of protecting arms opposing each other, so that the hot junction is disposed between the pair of protecting arms when it is disposed in the recess.

12. The method according to claim 1, wherein the refractory coating is made from a ceramic powder that undergoes densification to greater than 95% theoretical density.

13. A method of manufacturing a thermocouple comprising:
placing a distal end portion of a first thermocouple wire into physical contact with a distal end portion of a second thermocouple wire to form a splice;
forming a hot junction by laser-welding the splice to form a weld;
applying a refractory coating on the entire hot junction and at least a section of the distal end portions of the first thermocouple wire and the second thermocouple wire; and
placing the first and second thermocouple wires and the hot junction into a ceramic insulator body.

14. The method according to claim 13, wherein applying the refractory coating is accomplished using a process selected from the group consisting of physical vapor deposition, chemical vapor deposition, plasma enhanced chemical vapor deposition, plasma spray, and thick film.

15. The method according to claim 13, wherein the refractory coating has a continuous thickness between 50 microns and 150 microns.

16. The method according to claim 13, wherein the refractory coating is selected from the group consisting of Al₂O₃ and SiO₂.

17. The method according to claim 13, wherein the first thermocouple wire and the second thermocouple wire comprise a material selected from the group consisting of platinum and platinum-rhodium alloys.

18. The method according to claim 13, wherein ceramic insulator body defines a pair of passages extending along the length of the ceramic insulator body and a distal end portion having a recess, such that placing the joined thermocouple wires and the hot junction within the ceramic insulator body includes placing the first and second thermocouple wires into the passages and placing the distal end portions of the first and second thermocouple wires and the hot junction within the recess.

19. The method according to claim 13, wherein the refractory coating is made from a ceramic powder that undergoes densification to greater than 95% theoretical density.

20. The method according to claim 17, wherein the first thermocouple wire and the second thermocouple wire comprise dissimilar materials.

21. The method according to claim 18, wherein the ceramic insulator body further comprises a distal end including a pair of protecting arms opposing each other, such that placing the hot junction within the ceramic insulator body further includes placing the hot junction between the pair of protecting arms.
